(19) United States
(12) Patent Application Publication
(10) Pub. No.: US 2022/0013867 A1
(43) Pub. Date: Jan. 13, 2022

(54) CONNECTION MODULE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP); SUMITOMO ELECTRIC PRINTED CIRCUITS, INC., Shiga (JP); TOYOTA JIDOSHA KABUSHIKI KAISHA, Aichi-ken (JP)

(72) Inventors: Hideo TAKAHASHI, Mie (JP); Shinichi TAKASE, Mie (JP); Hiroki SHIMODA, Mie (JP); Kouichi NAGAMINE, Aichi-ken (JP); Masayuki UEDA, Aichi-ken (JP); Yoshifumi UCHITA, Shiga (JP); Takayuki TSUMAGARI, Shiga (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP); SUMITOMO ELECTRIC PRINTED CIRCUITS, INC., Shiga (JP); TOYOTA JIDOSHA KABUSHIKI KAISHA, Aichi-ken (JP)

(21) Appl. No.: 17/296,035

(22) PCT Filed: Nov. 1, 2019
(86) PCT No.: PCT/JP2019/043019

§ 371 Date: May 21, 2021

(30) Foreign Application Priority Data
Nov. 22, 2018 (JP) 2018-219300

(51) Int. Cl. H01M 50/519; H05K 1/02

(52) U.S. Cl. CPC H01M 50/519; H05K 2201/10037; H05K 1/0298; H05K 1/028

(57) ABSTRACT

A connection module is a module mounted on a power storage element group including power storage elements having electrode terminals and connecting the power storage elements. The connection module includes a FPC including wiring portions and bus bars connected to the wiring portions and connecting the electrode terminals of the power storage elements that are adjacent to each other. The FPC includes a first multi-layered portion including the wiring portions that are overlapped with each other by folding the FPC and includes a second multi-layered portion including the wiring portions that are overlapped with each other by folding the FPC.

### TECHNICAL FIELD

The technology disclosed herein relates to a connection module.

### BACKGROUND ART

A connection module for an electric automobile or a hybrid automobile includes a battery block and a connection module. The battery block includes battery cells and the connection module is attached to the battery block to connect the battery cells. A flexible printed wiring board with bus bars has been known as such a connection module (refer to Patent Document 1). The flexible printed wiring board includes a flexible printed circuit board (FPC) and bus bars that are connected to the flexible printed circuit board and connect electrode terminals of adjacent power storage elements.

### RELATED ART DOCUMENT

### Patent Document

[Patent Document 1] Japanese Unexamined Patent Application Publication No. 2014-86246

### SUMMARY OF THE INVENTION

### Problem to be Solved by the Invention

In the above configuration, a great number of bus bars are necessary for a great number of battery cells. If one flexible printed circuit board includes wirings for all of the bus bars, a width of the flexible printed circuit board is increased. However, the connection module arranged on the battery block has a limited wire routing space. Therefore, mounting of the connection module may be difficult if the width of the flexible printed circuit board becomes too large.

### Means for Solving the Problem

A connection module described herein is a connection module to be mounted on a power storage element group including power storage elements having electrode terminals and connecting the power storage elements. The connection module includes a flexible printed circuit board including routing portions, and connection members connected to the routing portions and connecting the electrode terminals of the power storage elements that are adjacent to each other. The flexible printed circuit board includes a multi-layered portion including the routing portions that are overlapped with each other by folding the flexible printed circuit board.

According to such a configuration, the width of the wiring portions can be reduced compared to a configuration in which the wirings for all the connecting members are arranged in a single layer routing structure. Therefore, the routing portions can be mounted within a limited routing space on the power storage element group.

In the above configuration, the connection module may further include a holding member that holds the connection members and the multi-layered portion.

According to such a configuration, the wiring portions that are overlapped with each other and the connecting members are collectively held and collectively mounted in a predefined position on the power storage element group. This improves operability of mounting the connection module on the power storage element group.

### Advantageous Effects of Invention

According to the connection module described herein, routing portions can be arranged within a limited wire routing space on a power storage element group.

### BRIEF DESCRIPTION OF THE DRAWINGS

FIG. 1 is a perspective view of a power storage module according to one embodiment.

FIG. 2 is a plan view of the power storage module according to the embodiment.

FIG. 3 is an enlarged view illustrating a portion surrounded by a frame R1 in FIG. 2.

FIG. 4 is a cross-sectional view taken along A-A line in FIG. 3.

FIG. 5 is a perspective view of a connection module according to the embodiment.

FIG. 6 is an enlarged view illustrating a portion surrounded by a frame R2 in FIG. 5.

FIG. 7 is a perspective view of a bus bar according to the embodiment.

FIG. 8 is a plan view of a flexible printed circuit board according to the embodiment.

FIG. 9 is a plan view of the unfolded flexible printed circuit board according to the embodiment.

FIG. 10 is a perspective view of a resin protector according to the embodiment.

FIG. 11 is an enlarged view illustrating a portion surrounded by a frame R3 in FIG. 10.

FIG. 12 is an enlarged perspective view illustrating a portion of the resin protector around a first connecting portion.

FIG. 13 is a plan view of the resin protector according to the embodiment.

FIG. 14 is an enlarged view illustrating a portion surrounded by a frame R4 in FIG. 12.

FIG. 15 is a plan view illustrating the power storage module including expandable/contractable portions that are expanded corresponding to position displacement of the electrode terminals.

### MODES FOR CARRYING OUT THE INVENTION

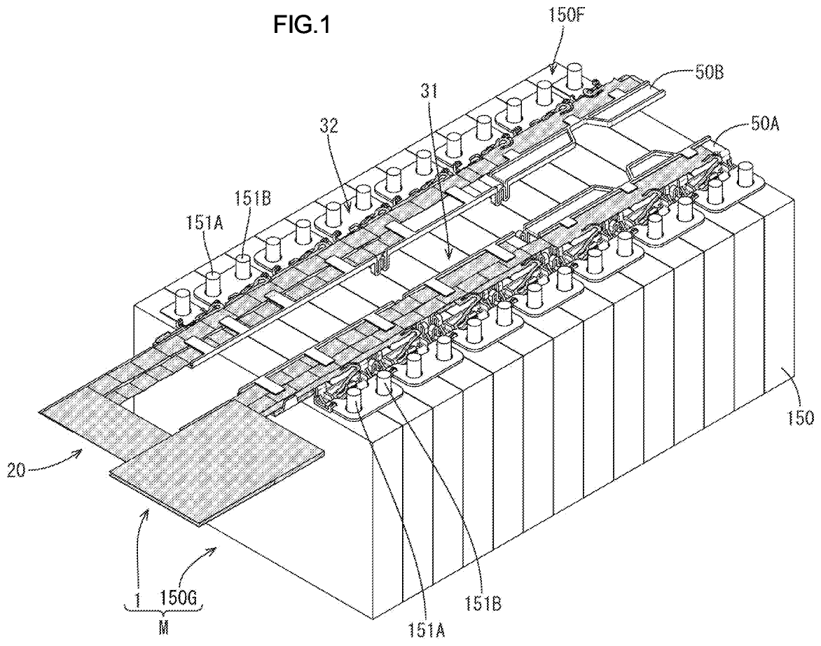

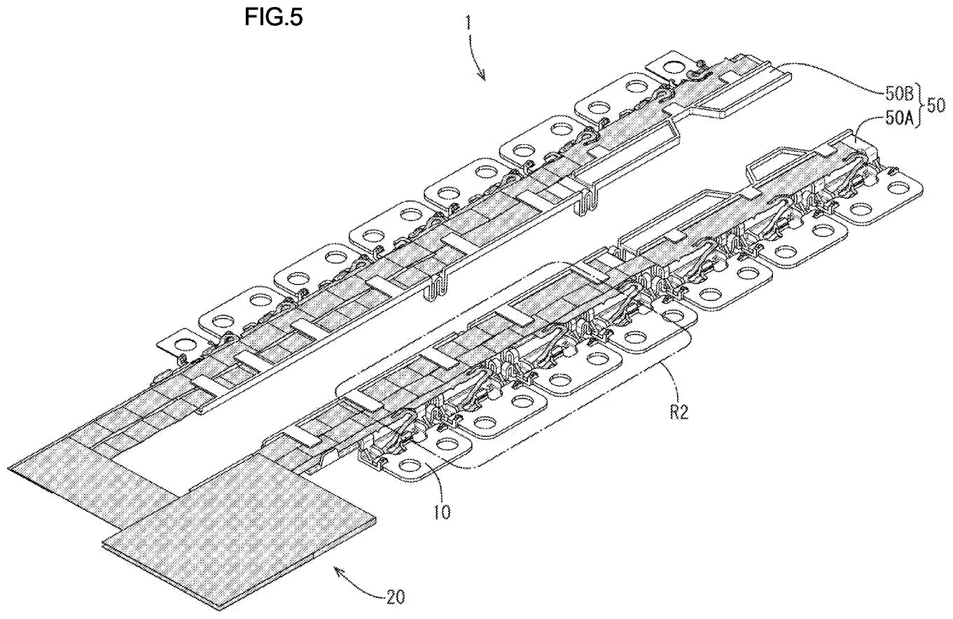

One embodiment will be described with reference to FIGS. 1 to 15. A connection module 1 according to this embodiment is included in a power storage module M that is used as a power source for driving a vehicle such as an electric automobile or a hybrid automobile. As illustrated in FIG. 1, the connection module 1 is attached to a power storage element group 150G including power storage elements 150 that are arranged in a row to connect the power storage elements 150 in series.

[Power Storage Element 150 and Power Storage Element Group 150G]

The power storage element 150 is a secondary battery, for example. As illustrated in FIG. 1, each of the power storage elements 150 has a rectangular parallelepiped flat shape and has an electrode mount surface 150F (an upper surface in FIG. 1) that is vertical to a surface of the power storage element 150 opposite an adjacent power storage element 150. Electrode terminals 151A, 151B are disposed on the electrode mount surface 150F. One of the electrode terminals 151A, 151B is an anode terminal 151A and another one is a cathode terminal 151B. Each of the electrode terminals 151A, 151B has a columnar shape and has threads on a peripheral surface thereof.

As illustrated in FIG. 1, the power storage elements 150 are arranged in a row and are configured as the power storage element group 150G. Among the power storage elements 150, every two adjacent power storage elements 150 are arranged such that the electrode terminals 151A, 151B having different polarities are disposed adjacent to each other (the anode terminal 151A of one power storage element 150 is disposed adjacent to the cathode terminal 151B of another power storage element 150 that is adjacent to the one power storage element 150).

[Connection Module 1]

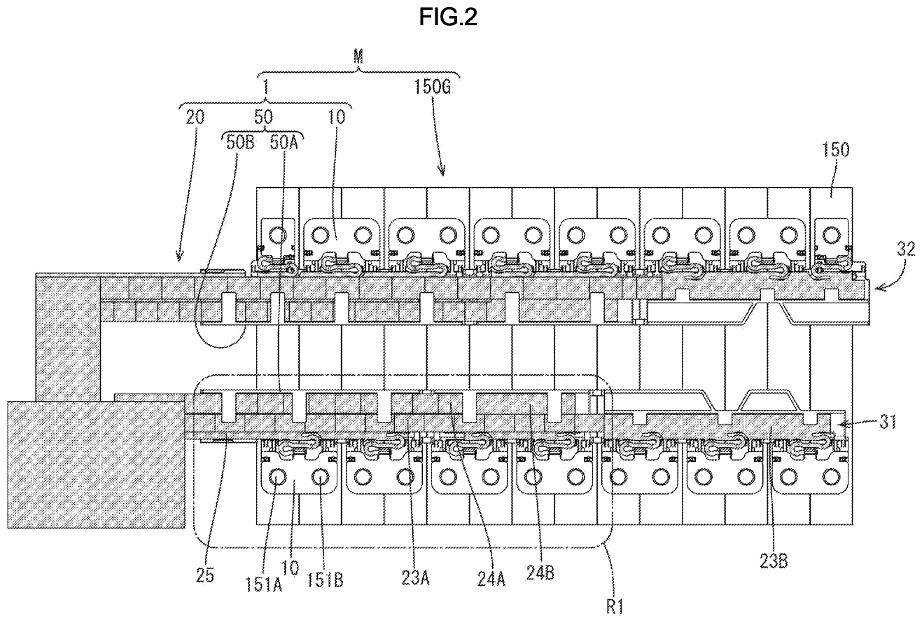

The connection module 1 is mounted on a surface (an upper surface in FIG. 1) of the power storage element group 150G including the electrode mount surfaces 150F of the power storage elements 150. As illustrated in FIG. 2, the connection module 1 includes a flexible printed circuit board (hereinafter, referred to as a FPC 20), bus bars 10 (corresponding to a connection member), and a resin protector (corresponding to a holding member). The bus bars 10 are connected to the FPC 20 and each of the bus bars 10 connects the anode terminal 151A and the cathode terminal 151B of the adjacent power storage elements 150. The resin protector 50 holds the bus bars 10 and the FPC 20.

(Bus Bar 10)

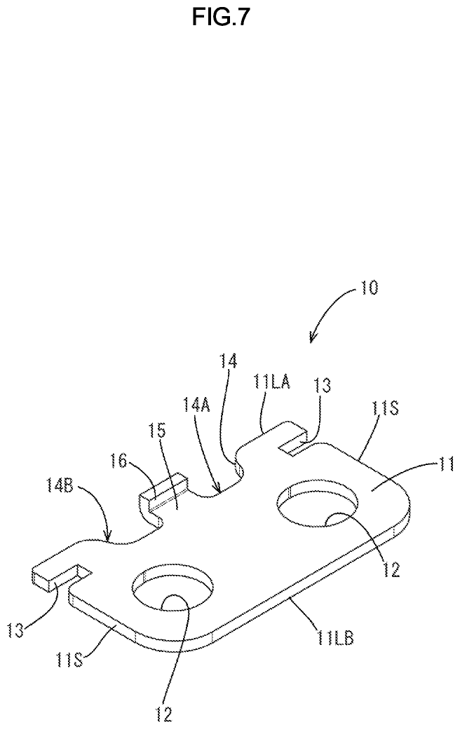

Each of the bus bars 10 is made of metal and includes an electrode connection portion 11, a FPC connection portion 15, and a stopper wall 16, as illustrated in FIG. 7. The electrode connection portion 11 connects the anode terminal 151A and the cathode terminal 151B of the adjacent power storage elements 150. The FPC connection portion 15 is continuous from the electrode connection portion 11 and connected to the FPC 20. The stopper wall 16 is continuous from the FPC connection portion 15.

The electrode connection portion 11 has a rectangular plate shape as a whole and has two electrode insertion holes 12 through which the electrode terminals 151A, 151B are inserted, respectively, and two recessed portions 13 to be fitted to the resin protector 50. The electrode connection portion 11 includes one of the electrode insertion holes 12 close to one of short sides 11S thereof and another one close to another one of the short sides 11S. One of the two recessed portions 13 is recessed from one of the short sides 11S of the electrode connection portion 11 and another one is recessed from the other one of the short sides 11S.

The electrode connection portion 11 has two long sides 11LA, 11LB and a connection recess 14 recessed from the long side 11LA. The connection recess 14 is defined by a first edge 14A that is parallel to the long side 11LA and two first side edges 14B that connect ends of the first edge 14A to the long side 11LA. The FPC connection portion 15 is a quadrangular plate portion that extends from the first edge 14A along a same plane surface as the electrode connection portion 11. The stopper wall 16 is a short wall plate portion that extends vertically from a distal end of the FPC connection portion 15.

(FPC 20)

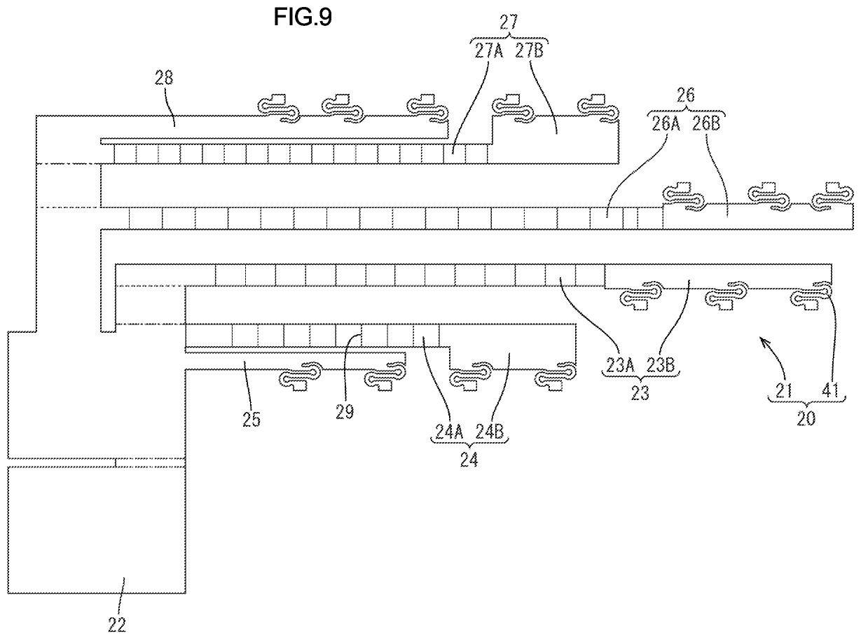

The FPC 20 is for electrically connecting the bus bars 10 and an ECU (electric control unit, not illustrated) and is not illustrated in detail. The FPC 20 includes conductive wirings made of a copper foil and an insulating resin film that covers both surfaces of the conductive wirings. As illustrated in FIG. 9, the FPC 20 includes a FPC body member 21 and first deformable portions 41 that are continuous from the FPC body member 21 and are connected to the respective bus bars 10.

As illustrated in FIG. 9, the FPC body member 21 includes an external connection portion 22 that is connected to the ECU and six wiring portions (a first wiring portion 23, a second wiring portion 24, a third wiring portion 25, a fourth wiring portion 26, a fifth wiring portion 27, and a sixth wiring portion 28: corresponding to a routing portion).

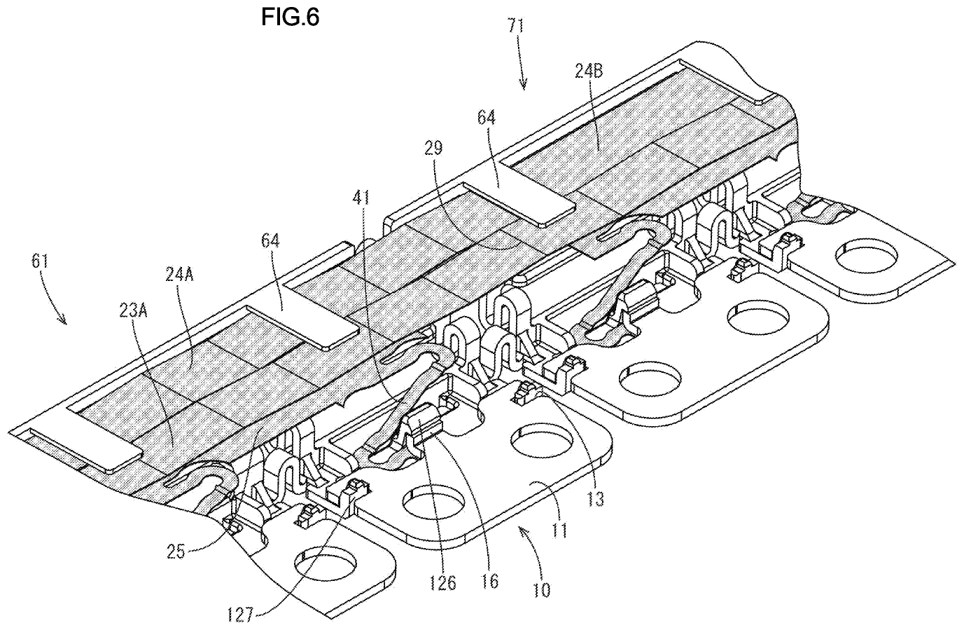

The first wiring portion 23 includes a first expandable/contractable portion 23A extending from the external connection portion 22 and a first bus bar mount portion 23B that is continuous from an extended end of the first expandable/contractable portion 23A. The first wiring portion 23 is a thin elongated belt shaped portion as a whole. The first expandable/contractable portion 23A is slightly bent along fold lines 29 so as to be bent in a waveform including projection portions and recess portions alternately (refer to FIG. 6). Accordingly, the first expandable/contractable portion 23A can be expanded or contracted by changing the bending angle. This allows the first bus bar mount portion 23B to move in a direction to be closer to and farther away from the external connection portion 22.

The second wiring portion 24 similarly includes a second expandable/contractable portion 24A extending from the external connection portion 22 and a second bus bar mount portion 24B that is continuous from an extended end of the second expandable/contractable portion 24A. The fourth wiring portion 26 similarly includes a fourth expandable/contractable portion 26A extending from the external connection portion 22 and a fourth bus bar mount portion 26B that is continuous from an extended end of the fourth expandable/contractable portion 26A. The fifth wiring portion 27 similarly includes a fifth expandable/contractable portion 27A extending from the external connection portion 22 and a fifth bus bar mount portion 27B that is continuous from an extended end of the fifth expandable/contractable portion 27A. The second expandable/contractable portion 24A, the fourth expandable/contractable portion 26A, and the fifth expandable/contractable portion 27A have configurations similar to that of the first expandable/contractable portion 23A except for having different lengths.

Each of the third wiring portion 25 and the sixth wiring portion 28 extends from the external connection portion 22. The third wiring portion 25 differs from the four wiring portions 23, 24, 26, 27 and does not include an expandable/contractable portion.

The six wiring portions 23, 24, 25, 26, 27, 28 extend in the same direction from the external connection portion 22 and are arranged in parallel to each other.

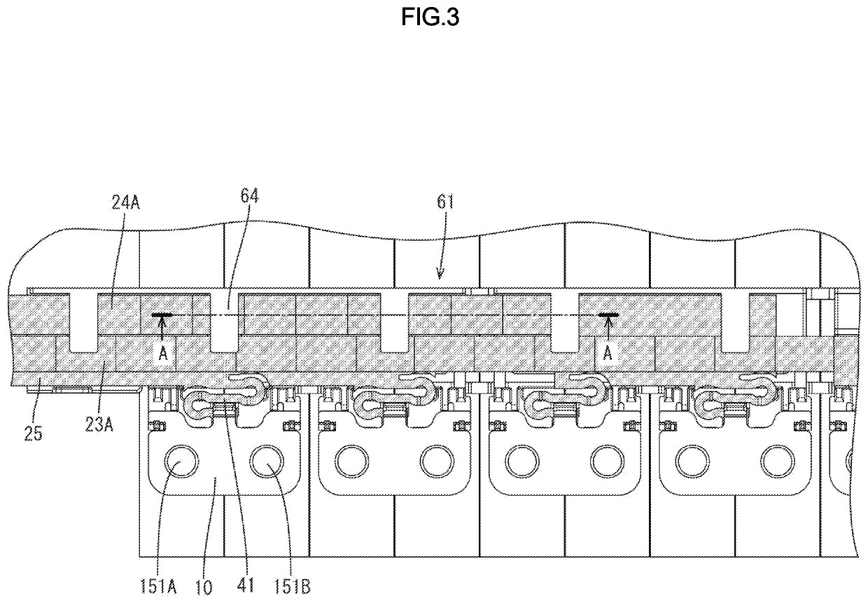

As illustrated in FIGS. 3 and 9, the first deformable portion 41 is an elongated S-shaped plate spring portion that is continuous from the FPC body member 21. As illustrated in FIG. 9, some of the first deformable portions 41 are continuous from the third wiring portion 25, another ones of the first deformable portions 41 are continuous from the sixth wiring portion 28, and some of the rest of them are continuous from each of the four bus bar mount portion 23B, 24B, 26B, 27B. A portion of the wirings is exposed at a distal end of the first deformable portion 41 as a connection land (not illustrated) that is a connection portion, and the FPC connection portion 15 is connected to the connection land with soldering.

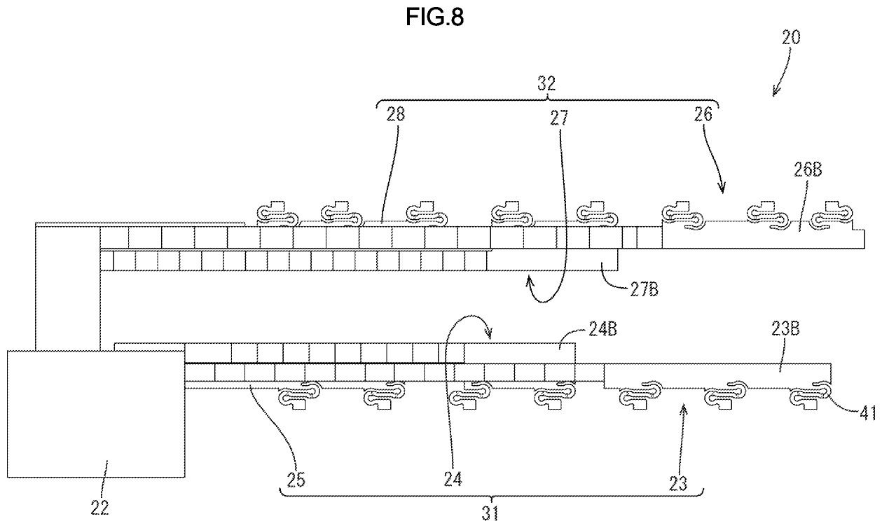

The external connection portion 22 of the FPC body member 21 is folded along mountain fold lines illustrated by broken lines and valley fold lines illustrated by dashed-dotted lines illustrated in FIG. 9. Accordingly, as illustrated in FIG. 8, the first wiring portion 23, the second wiring portion 24, and the third wiring portion 25 are configured as a multi-layered portion (a first multi-layered portion 31), and the fourth wiring portion 26, the fifth wiring portion 27, and the sixth wiring portion 28 are configured as another multi-layered portion (a second multi-layered portion 32).

As illustrated in FIG. 8, the first multi-layered portion 31 has a two-layer structure including a first layer and a second layer disposed on the first layer. The first layer includes the second wiring portion 24 and the third wiring portion 25. The second layer includes the first wiring portion 23. In the first multi-layered portion 31, the third wiring portion 25, the second bus bar mount portion 24B, and the first bus bar mount portion 23B are arranged along a line in this order from the external connection portion 22. The first deformable portions 41 that are continuous to the third wiring portion 25, the second bus bar mount portion 24B, and the first bus bar mount portion 23B are arranged in a row.

Similarly, the second multi-layered portion 32 has a two-layer structure including a first layer and a second layer disposed on the first layer. The first layer includes the fifth wiring portion 27 and the sixth wiring portion 28. The second layer includes the fourth wiring portion 26. In the second multi-layered portion 32, the sixth wiring portion 28, the fifth bus bar mount portion 27B, and the fourth bus bar mount portion 26B are arranged along a line in this order from the external connection portion 22. The first deformable portions 41 that are continuous to the sixth wiring portion 28, the fifth bus bar mount portion 27B, and the fourth bus bar mount portion 26B are arranged in a row.

The first bus bar mount portion 23B is allowed to move in the direction to be closer to and farther away from the second bus bar mount portion 24B that is disposed adjacent thereto by the expansion and contraction of the first expandable/contractable portion 23A. The second bus bar mount portion 24B is allowed to move in the direction to be closer to and farther away from the first bus bar mount portion 23B and the third wiring portion 25 that are disposed adjacent thereto by the expansion and contraction of the second expandable/contractable portion 24A. Similarly, the fourth bus bar mount portion 26B is allowed to move in the direction to be closer to and farther away from the fifth bus bar mount portion 27B that is disposed adjacent thereto by the expansion and contraction of the fourth expandable/contractable portion 26A. The fifth bus bar mount portion 27B is allowed to move in the direction to be closer to and farther away from the fourth bus bar mount portion 26B and the sixth wiring portion 28 that are disposed adjacent thereto by the expansion and contraction of the fifth expandable/contractable portion 27A. Such configurations solve problems caused by the position displacement of the electrode terminals 151A, 151B due to the dimension tolerance of the power storage group 150G.

(Resin Protector 50)

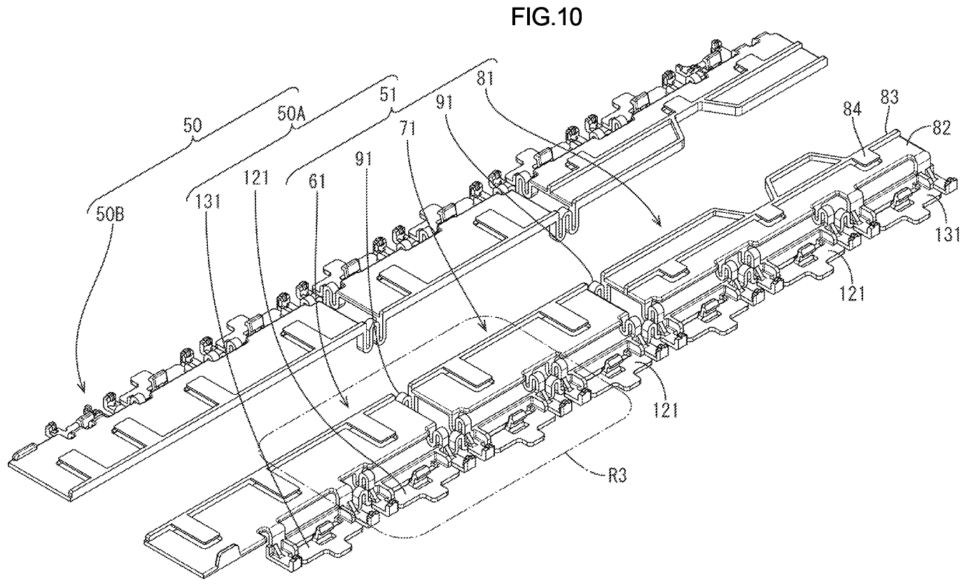

The resin protector 50 is made of synthetic resin and includes a first protector 50A that holds the first multi-layered portion 31 and a second protector 50B that holds the second multi-layered portion 32, as illustrated in FIG. 10. The second protector 50B has a configuration substantially similar to that of the first protector 50A except for a detailed structure such as a stopper structure with respect to the second multi-layered portion 32. Therefore, in the following description, the first protector 50A will be described as an example.

The first protector 50A holds the first multi-layered portion 31. As illustrated in FIG. 10, the first protector 50A includes a first FPC holding portion 51 that holds the FPC body member 21, and bus bar holding portions 121, 131 that hold the respective bus bars 10.

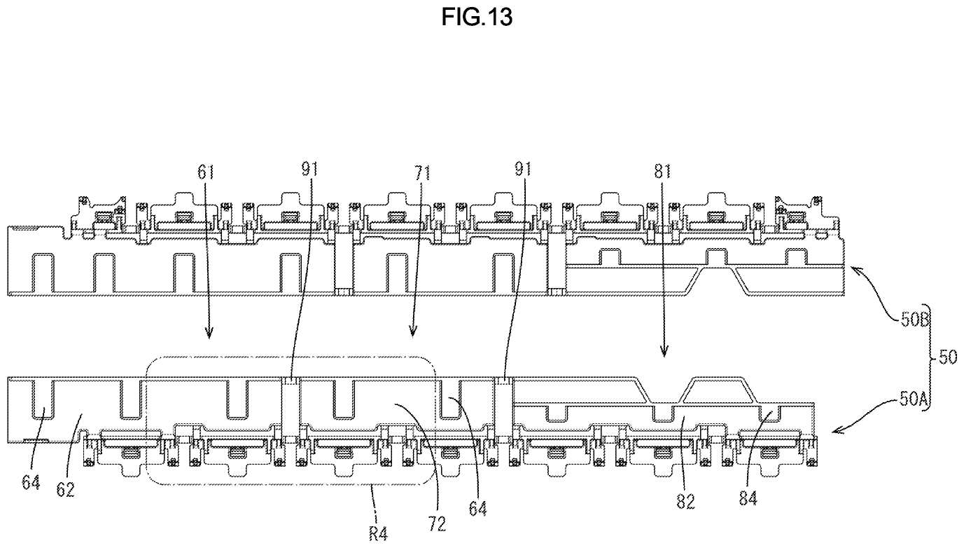

As illustrated in FIGS. 10 and 13, the first FPC holding portion 51 includes three holding units (a first holding unit 61, a second holding unit 71, a third holding unit 81) and two first connecting portions 91 that connect adjacent ones of the holding units 61, 71, 81. The first FPC holding portion 51 is an elongated narrow rectangular plate that has a substantially same size as that of the first multi-layered portion 31 as a whole. The first holding unit holds the third wiring portion 25, the second expandable/contractable portion 24A, and a portion of the first expandable/contractable portion 23A overlapping the third wiring portion 25. The second holding unit 71 holds the second bus bar mount portion 24B and a portion of the first expandable/contractable portion 23A overlapping the second bus bar mount portion 24B. The third holding unit 81 holds the first bus bar mount portion 23B.

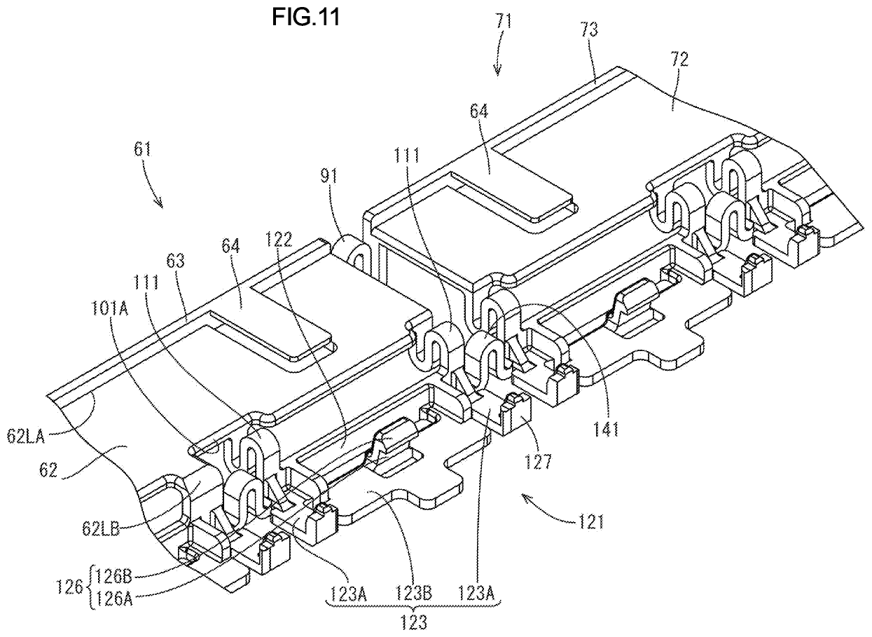

As illustrated in FIGS. 11 and 13, the first holding unit 61 includes a first mount plate 62, a first side rib 63 projecting from the first mount plate 62, and retaining pieces 64. The retaining pieces 64 are continuous from the first side rib 63.

As illustrated in FIG. 13, the first mount plate 62 is a rectangular plate as a whole. As illustrated in FIG. 11, the first side rib 63 is a thin elongated portion that projects from a long side 62LA (the upper one in FIG. 11) out of the long sides 62LA, 62LB of the first mount plate 62. As illustrated in FIG. 11, each of the retaining pieces 64 is an elongated narrow plate member that extends from the first side rib 63 parallel to the first mount plate 62 and retains and sandwiches the first multi-layered portion 31 with the first mount plate 62.

Similarly, the second holding unit 71 includes a second mount plate 72, a second side rib 73 projecting from the second mount plate 72, and the retaining pieces 64 that are continuous from the second side rib 73. The third holding unit 81 includes a third mount plate 82, a third side rib 83 projecting from the third mount plate 82, and retaining pieces 84 that are continuous from the third side rib 83.

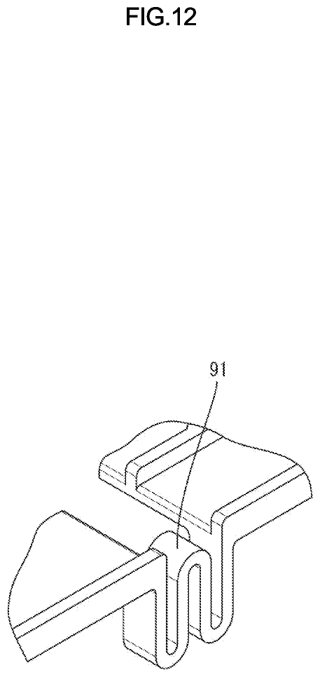

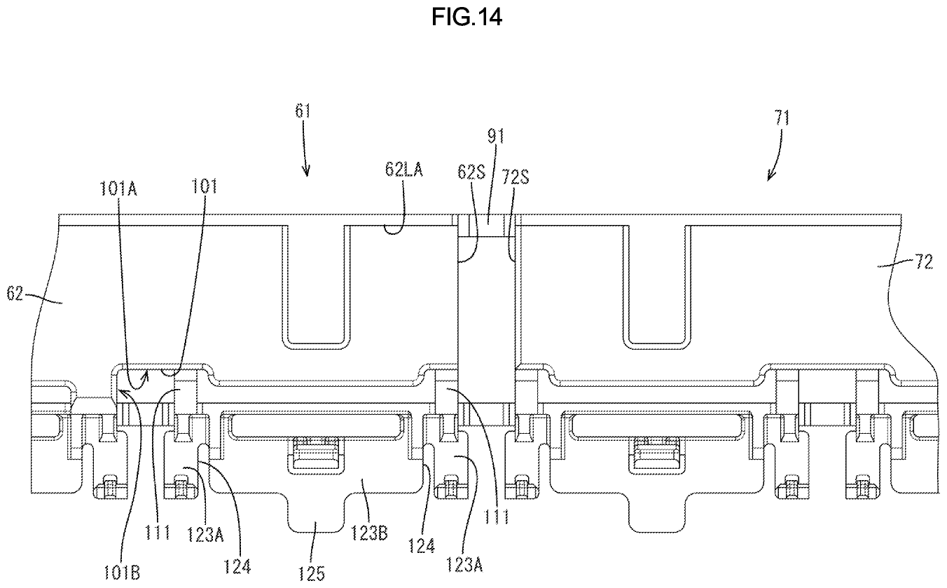

As illustrated in FIG. 12, each of the two first connecting portions 91 is a plate spring that is bent in a W-shape. As illustrated in FIGS. 11 and 14, one of the first connecting portions 91 connects the first mount plate 62 and the second mount plate 72. One end of the W-shape is connected to the short side 62S of the first mount plate 62 and another end of the W-shape is connected to the short side 72S of the second mount plate 72. Another one of the first connecting portions 91 similarly connects the second mount plate 72 and the third mount plate 82. The three holding units 61, 71, 81 are connected to each other by the first connecting portions 91 so as to be movable in the direction to be closer to and farther away from each other. According to such a configuration, the distances between the three holding units 61, 71, 81 can be changed corresponding to the change in the distances between the first bus bar mount portion 23B, the second bus bar mount portion 24B, and the third wiring portion 25.

As illustrated in FIG. 10, among the bus bar holding portions 121, 131, one disposed at an end of the first holding unit 61 opposite from the second holding unit 71 and one disposed at an end of the third holding unit 81 opposite from the second holding unit 71 are fixed bus bar holding portions 131 and other ones are movable bus bar holding portions 121 that are connected to the holding units 61, 71, 81, respectively, via second deformable portions 111. In the following, the second deformable portions 111, the movable bus bar holding portions 121, and the fixed bus bar holding portion 131 included in the first holding unit 61 will be described. The configurations of the second deformable portions 111 and the bus bar holding portions 121, 131 included in the second holding unit 71 and the third holding unit 81 same as those of the first holding unit 61 are represented by the same symbols as those of the first holding unit 61 and will not be described.

As illustrated in FIG. 14, the first mount plate includes a recessed portion 101 for spring that is recessed inward from the long side 62LB, which is another one of the long sides 62LA, 62LB (the lower one in FIG. 11). The recessed portion 101 is defined by a second edge 101A that is parallel to the long side 62LB and two second side edges 101B that connect ends of the second edge 101A to the long side 62LB.

As illustrated in FIG. 11, the second deformable portion 111 is an elongated plate spring portion that extends from the second edge 101A while being bent. The second deformable portion 111 has an S-shape and extends vertically with respect to the first mount plate 62 and is folded back to extend closer to the first mount plate 62 and is folded back again to extend farther away from the first mount plate 62. A set of two adjacent second deformable portions 111 are connected to one movable bus bar holding portion 121.

As illustrated in FIGS. 11 and 14, the movable bus bar holding portion 121 includes a back plate 122 that is continuous from the second deformable portion 111, a bottom plate portion 123 that is continuous from the back plate 122, an extended portion 125 extending from the bottom plate portion 123, a first bus bar stopper 126, and two second bus bar stoppers 127.

As illustrated in FIG. 11, the back plate 122 is a plate that is vertical to the first mount plate 62 and is connected to a distal end of each of the two second deformable portions 111.

As illustrated in FIGS. 11 and 14, the bottom plate portion 123 is a plate that extends vertically from the back plate 122 in an opposite direction from the first mount plate 62 and includes two slits 124. Each of the two slits 124 extends from the extended edge of the bottom plate portion 123 toward the back plate 122. The bottom plate portion 123 is divided into two edge plate portions 123A at two ends thereof and a middle plate portion 123B at a middle by the slits 124. As illustrated in FIG. 14, the extended portion 125 is a plate portion that extends from the extended edge of the middle plate portion 123B along a same plane surface as that of the bottom plate portion 123.

As illustrated in FIG. 11, the first bus bar stopper 126 includes a first warping portion 126A and a first stopper projection 126B. The first warping portion 126A extends from the middle plate portion 123B and is spaced away from the back plate 122. The first stopper projection 126B projects from the extended end of the first warping portion 126A in a direction opposite from the back plate 122. The first warping portion 126A is slightly tilted so as to be farther away from the back plate 122 as it extends from the middle plate portion 123B.

As illustrated in FIG. 11, the two second bus bar stoppers 127 extend from the two edge plate portions 123A, respectively. Although details are not illustrated, each second bus bar stopper 127 includes a second warping portion and a second stopper projection. The second warping portions extend vertically from the extended edges of the two edge plate portions 123A, respectively, and the second stopper projections project from the distal ends of the second warping portions toward the back plate 122, respectively.

The fixed bus bar holding portion 131 does not have the second deformable portion 111 but has a configuration similar to that of the movable bus bar holding portion 121. The fixed bus bar holding portion 131 includes a back plate extending from the long side 62LB of the first mount plate 62. The components of the fixed bus bar holding portion 131 same as those of the movable bus bar holding portion 121 are represented by the same symbols as those of the movable bus bar holding portion 121 and will not be described.

As illustrated in FIG. 10, the bus bar holding portions 121, 131 are arranged in a row. As illustrated in FIG. 11, two adjacent movable bus bar holding portions 121 are connected to each other by a U-shaped second connecting portion 141. Similarly, the fixed bus bar holding portion 131 and the movable bus bar holding portion 121 next thereto are connected to each other by the second connecting portion 141.

[Assembling of Connection Module 1]

One example of steps of assembling the connection module 1 having the above configuration will be described below.

First, the bus bars 10 are connected to the FPC 20. The FPC connection portions 15 of the respective bus bars 10 are put on the respective connection portions of the FPC 20 and the FPC connection portions 15 and the connection portions are connected to each other, respectively, with reflow soldering. The bus bars 10 are connected to the FPC body member 21 via the first deformable portions 41. Accordingly, the bus bars 10 can freely move to some extent with respect to the FPC body member 21 by the deformation of the first deformable portions 41.

Next, the FPC 20 connected to the bus bars 10 is mounted on the resin protector 50.

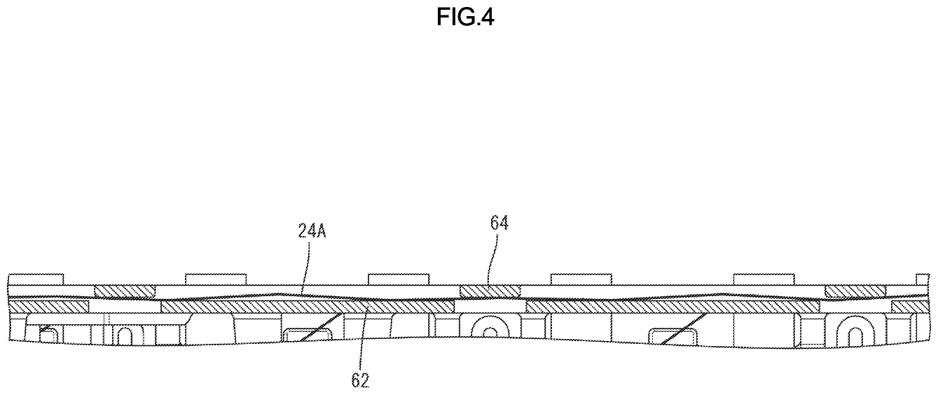

First, the first multi-layered portion 31 is mounted on the first protector 50. The first multi-layered portion 31 is inserted into spaces between the mount plates 62, 72, 82 and the retaining pieces 64, 84 to be placed on the mount plates 62, 72, 82. Thus, the first multi-layered portion 31 is held by the first FPC holding portion 51. A distance between the retaining pieces 64 and the first mount plate 62 is greater than the thickness of the first multi-layered portion 31. As illustrated in FIG. 4, the second expandable/contractable portion 24A is sandwiched between and held by the retaining pieces 64 and the first mount plate 62 so as to be deformed and bent to some extent. Similarly, the first expandable/contractable portion 23A is held to be deformed and bent to some extent.

The second multi-layered portion 32 is similarly mounted on the second protector 50B.

Next, the bus bars 10 are mounted on the bus bar holding portions 121, 131, respectively. Each electrode connection portion 11 is pushed toward the bottom plate portion 123 while the first bus bar stopper 126 and the second bus bar stoppers 127 being warped. When the electrode connection portion 11 is contacted with the bottom plate portion 123, as illustrated in FIG. 6, the first bus bar stopper 126 elastically restores its original shape and the stopper wall 16 is sandwiched between the middle plate portion 123B and the first stopper projection 126B. The second bus bar stoppers 127 are inserted in the respective recessed portions 13 and fitted to the electrode connection portion 11. Thus, the bus bars 10 are fixed to the bus bar holding portions 121, 131, respectively. In such a configuration, the bus bars 10 are allowed to move freely to some extent with respect to the FPC body member 21 since the first deformable portions 41 can be deformed. Therefore, the bus bars 10 can be mounted on the bus bar holding portions 121, 131, respectively, easily. The bus bars 10 are easily mounted on the bus bar holding portions 121, 131, respectively, only by pushing the bus bars 10 toward the bottom plate portion 123.

[Mounting of Connection Module 1 on Power Storage Element Group 150G]

One example of steps of mounting the connection module 1 having the above configuration on the power storage element group 150G will be described below.

As illustrated in FIG. 1, the connection module 1 is disposed in a predefined position on the power storage element group 150G and the electrode terminals 151A, 151B are inserted in the electrode insertion holes 12 of the bus bars 10, respectively. Then, nuts, which are not illustrated, are screwed on the respective electrode terminals 151A, 151B to connect the electrode terminals 151A, 151B and each of the bus bars 10.

As illustrated in FIG. 1, the first protector 50A is fitted to one of the two rows of the electrode terminals 151A, 151B (a lower right row in FIG. 1) and the bus bars 10 connected to the first wiring portion 23, the second wiring portion 24, and the third wiring portion 25 included in the first multi-layered portion 31 are connected to the electrode terminals 151A, 151B of the one row. The second protector 50B is fitted to another one of the two rows of the electrode terminals 151A, 151B (an upper left row in FIG. 1) and the bus bars 10 connected to the fourth wiring portion 26, the fifth wiring portion 27, and the sixth wiring portion 28 included in the second multi-layered portion 32 are connected to the electrode terminals 151A, 151B of the other row.

The first multi-layered portion 31 that is connected to the electrode terminals 151A, 151B of the one row includes the wiring portions 23, 24, 25 that are overlapped each other. According to such a configuration, the width of each wiring portion 23, 24, 25 and the width of the first multi-layered portion 31 including the overlapped wiring portions 23, 24, 25 can be reduced compared to a configuration in which the wirings for all the bus bars 10 to be connected to the electrode terminals 151A, 151B of the one row are arranged in a single layer routing structure. The same effects can be obtained in the second multi-layered portion 32. Accordingly, the routing portions can be mounted within a limited routing space on the power storage element group 150G.

The connection module 1 includes the resin protector 50 and the resin protector 50 includes the first protector 50A and the second protector 50B. The first protector 50A holds the first multi-layered portion 31 and the bus bars 10 that are connected to the wirings 23, 24, 25 of the first multi-layered portion 31. According to such a configuration, the first protector 50A collectively holds the wirings 23, 24, 25 that are overlapped with each other and the bus bars 10 and collectively mount the wirings 23, 24, 25 and the bus bars 10 in a predefined position on the power storage element group 150G. Similarly, the second protector 50B collectively holds the wiring portions 26, 27, 28 that are overlapped with each other and the bus bars 10 and collectively mount the wiring portions 26, 27, 28 and the bus bars 10 in a predefined position on the power storage element group 150G. This improves operability of mounting the connection module 1 on the power storage element group 150G.

As previously described, in the first multi-layered portion 31, the first bus bar mount portion 23B, the second bus bar mount portion 24B, and the third wiring portion 25 are movable with respect to each other. According to such a configuration, problems caused by the position displacement of the electrode terminals 151A, 151B due to the dimension tolerance of the power storage element group 150G can be solved.

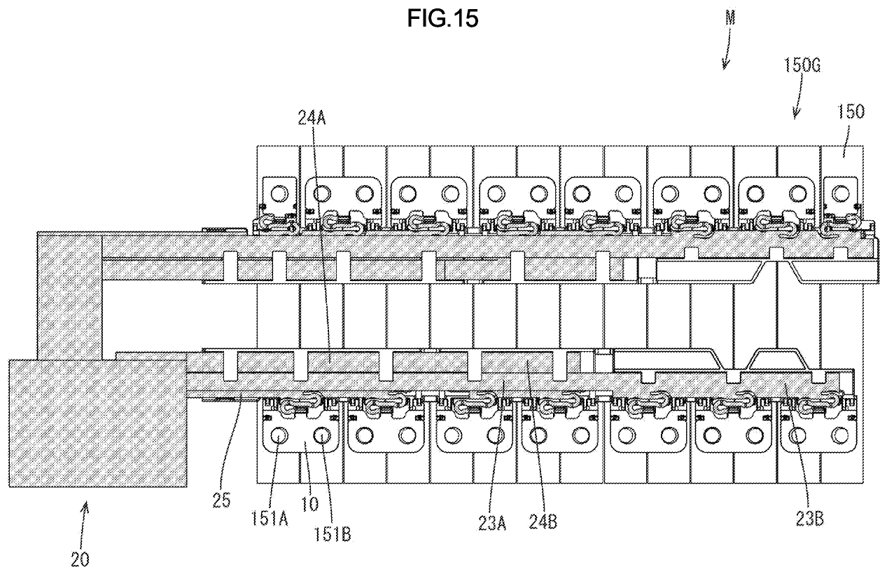

For example, if the distance between the electrode terminals 151A, 151B is smaller than the predefined design dimension, the first expandable/contractable portion 23A is deformed and bent to reduce the length thereof and the distance between the first bus bar mount portion 23B and the second bus bar mount portion 24B becomes smaller, as illustrated in FIG. 2. Similarly, the second expandable/contractable portion 24A is deformed and bent to reduce the length thereof and the distance between the second bus bar mount portion 24B and the third wiring portion 25 becomes smaller. If the distance between the electrode terminals 151A, 151B is greater than the predefined design dimension, the first expandable/contractable portion 23A is expanded to increase the distance between the first bus bar mount portion 23B and the second bus bar mount portion 24B, as illustrated in FIG. 15. Similarly, the second expandable/contractable portion 24A is expanded to increase the distance between the second bus bar mount portion 24B and the third wiring portion 25. Such configurations and operations are similarly obtained in the second multi-layered portion 32.

The distances between the adjacent ones of the three holding units 61, 71, 81 of the first protector 50A can be changed according to the change in the distances between the first bus bar mount portion 23B, the second bus bar mount portion 24B, and the third wiring portion 25. Therefore, the movement of the first bus bar mount portion 23B, the second bus bar mount portion 24B, and the third wiring portion 25 is not hindered by the first protector 50A. The same effects are obtained in the second protector 50B.

### SUMMARY

As previously described, according to the present embodiment, the connection module 1 is a module that is mounted on the power storage element group 150G including the power storage elements 150 having the electrode terminals 151A, 151B and connects the power storage elements 150. The connection module 1 includes the FPC 20 including the wiring portions 23, 24, 25, 26, 27, 28 and the bus bars 10 that are connected to the wiring portions 23, 24, 25, 26, 27, 28 and connect the electrode terminals 151A, 151B of the adjacent power storage elements 150. By folding the FPC 20, the wiring portions 23, 24, 25 are overlapped with each other to be configured as the first multi-layered portion 31 and the wiring portions 26, 27, 28 are overlapped with each other to be configured as the second multi-layered portion 32.

According to such a configuration, the width of each wiring portion 23, 24, 25, 26, 27, 28 can be reduced compared to a configuration in which the wirings (a conductive routing structure) for all the bus bars 10 are arranged in a single layer routing structure. Therefore, the routing portions can be mounted within a limited routing space on the power storage element group 150G.

The connection module 1 includes the resin protector 50 that holds the bus bars 10, the first multi-layered portion 31, and the second multi-layered portion 32.

According to such a configuration, the wiring portions 23, 24, 25, 26, 27, 28 that are overlapped with each other and the bus bars 10 are collectively held and collectively mounted in a predefined position on the power storage element group 150G. This improves operability of mounting the connection module 1 on the power storage element group 150G.

### OTHER EMBODIMENTS

The technology disclosed herein is not limited to the embodiment described above and illustrated in the drawings. For example, the following embodiments will be included in the technical scope of the technology.

(1) In the above embodiment, the first multi-layered portion 31 includes three wiring portions 23, 24, 25; however, a multi-layered portion may include two, four or more routing portions.

(2) In the above embodiment, the first multi-layered portion 31 has a two-layer structure; however, a multi-layered portion may include three layers or more. In the above embodiment, the first layer includes the second wiring portion 24 and the third wiring portion 25 and the second layer includes the first wiring portion 23; however, one layer may include three or more routing portions.

(3) The configuration of folding of the flexible printed circuit board for the multi-layered portion is not limited to the one in the above embodiment. For example, a long flexible printed circuit board may be folded along a fold line that is vertical to a side edge.

(4) In the above embodiment, the resin protector 50 includes the retaining pieces 64, 84; however, the holding member does not necessarily have the configuration for holding the flexible printed circuit board described in the above embodiment. For example, the holding member may include a pin and the pin may be inserted in a pin hole provided in the flexible printed circuit board, or the holding member may include a stopper and the flexible printed circuit board may be fitted to the stopper.

### EXPLANATION OF SYMBOLS

1: Connection module
10: Bus bar (connection member)
20: FPC (flexible printed circuit board)
23: First wiring portion (routing portion)
24: Second wiring portion (routing portion)
25: Third wiring portion (routing portion)
26: Fourth wiring portion (routing portion)
27: Fifth wiring portion (routing portion)
28: Sixth wiring portion (routing portion)
31: First multi-layered portion (multi-layered portion)
32: Second multi-layered portion (multi-layered portion)
50: Resin protector (holding member)
150: Power storage element
150G: Power storage element group
151A: Anode terminal (electrode terminal)
151B: Cathode terminal (electrode terminal)

1. A connection module to be mounted on a power storage element group including power storage elements having electrode terminals and connecting the power storage elements, the connection module comprising:
a flexible printed circuit board including routing portions; and
connection members connected to the routing portions and connecting the electrode terminals of the power storage elements that are adjacent to each other, wherein
the flexible printed circuit board includes a multi-layered portion including the routing portions that are overlapped with each other by folding the flexible printed circuit board.

2. The connection module according to claim 1, further comprising a holding member that holds the connection members and the multi-layered portion.
